(19) United States
(12) Patent Application Publication
(10) Pub. No.: US 2008/0305580 A1
(43) Pub. Date: Dec. 11, 2008

(54) BONDING OF STRUCTURES TOGETHER INCLUDING, BUT NOT LIMITED TO, BONDING A SEMICONDUCTOR WAFER TO A CARRIER

(76) Inventors: Alexander J. Berger, Palo Alto, CA (US); Sergey Savastiouk, San Jose, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/759,652

(22) Filed: Jun. 7, 2007

(51) Int. Cl. H01L 21/00; B23K 37/00

(52) U.S. Cl. 438/118; 156/580; 257/E23.003

(57) ABSTRACT

An expandable membrane (280), e.g. a membrane that is elastic and/or has a corrugated edge, is expanded to exert more uniform pressure over a semiconductor wafer (110) or a carrier (254) to bond the wafer to the carrier.

The present invention relates to bonding of structures to other structures. Some embodiments involve bonding a semiconductor wafer to a carrier in order to simplify wafer handling in fabrication of integrated circuits.

A semiconductor wafer can be bonded to a carrier to strengthen the wafer against mechanical stresses. The bonding can be performed with a double-sided adhesive tape. The carrier and the wafer are placed opposite each other and are pressed together with a plunger or a roller to squeeze out any air bubbles at the adhesive interface and form a strong bond.

### SUMMARY

This section summarizes some features of the invention. Other features are described in the subsequent sections. The invention is defined by the appended claims which are incorporated into this section by reference.

Some embodiments of the present invention provide bonding apparatus and methods which are suitable not only for thicker wafers (e.g. 600 μm or larger) but also for thin, possibly warped silicon wafers having a thickness of 100 μm, 50 μm, or even less. The invention is not limited to silicon wafers or particular thickness values however.

The inventors have observed that the pressure on the wafer and the carrier should preferably be as uniform as possible during bonding. The pressure must be sufficiently high throughout the wafer/carrier structure to form a strong bond and prevent air pocket (air bubble) formation between the wafer and the carrier. However, excessive pressure can damage the wafer and/or make subsequent debonding difficult. Therefore, the pressure should preferably be uniform to ensure sufficient minimal pressure without excessive maximum pressure. More uniform pressure can be achieved using an expandable membrane. For example, an elastic membrane can be stretched by gas (e.g. air) to put pressure onto an entire outer surface of the wafer or the carrier (i.e. the surface opposite to the bonding surface). The membrane at least partially conforms to the outer surface to provide a more uniform pressure over the surface. Also, an elastic or non-elastic membrane with the corrugated edge can be used.

In some embodiments, the bonding is performed in vacuum to reduce the danger of air pocket formation between the wafer and the carrier. If the wafer is warped, it is flattened by an electrostatic chuck (a vacuum chuck is not used as it is less effective in vacuum).

The invention is applicable to bonding of structures other than semiconductor wafers. Other features are described below. The invention is defined by the appended claims.

### BRIEF DESCRIPTION OF THE DRAWINGS

FIG. 1 illustrates a semiconductor wafer used in some embodiments of the present invention.

FIGS. 2-3 illustrate different stages of a bonding process according to some embodiments of the present invention.

FIG. 4 illustrates a wafer bonded to a carrier according to some embodiments of the present invention.

FIG. 5 illustrates a bonding process according to some embodiments of the present invention.

### DESCRIPTION OF SOME EMBODIMENTS

The embodiments described in this section illustrate but do not limit the invention. The invention is defined by the appended claims.

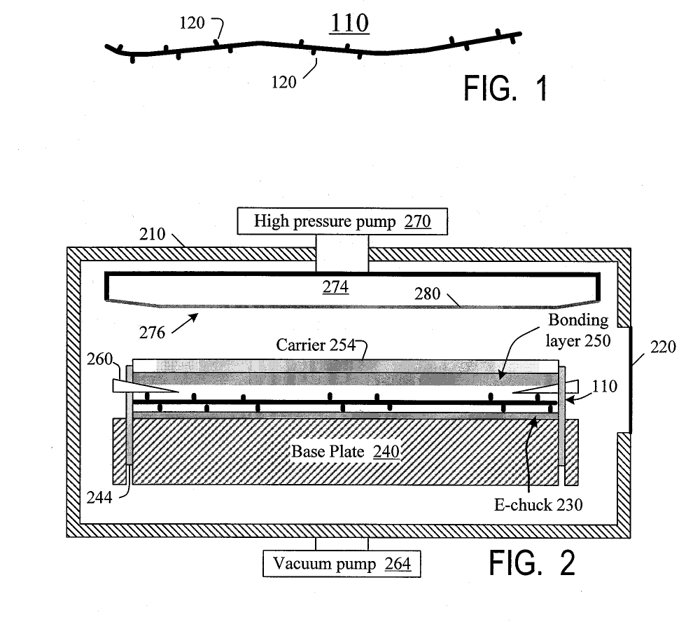

FIG. 1 shows a semiconductor wafer 110 (e.g. a silicon wafer) partially processed to form protruding features 120 on the top and/or bottom surfaces. Features 120 may include conductive contact pads (e.g. copper posts) and/or other integrated circuit elements (conductors and dielectric and semiconductor features). The wafer has been thinned, and is warped unless supported by a suitable holder that could flatten the wafer (e.g. a gas vortex holder). When the wafer is bonded to a carrier and described below, the wafer processing will continue and may involve photolithography, deposition, etching, dicing, and/or other operations.

The bonding operation is performed in a vacuum chamber 210 (FIG. 2). The wafer is loaded into the vacuum chamber via the chamber's loading port 220 by a robot (not shown) holding the wafer in a suitable end effector. In some embodiments, the end effector flattens the wafer using vacuum or a non-contact mechanism (e.g. gas vortices or using the Bernoulli effect). The robot places the wafer on an electrostatic chuck 230 which lies on a base plate 240 in chamber 210. The electrostatic chuck keeps the wafer flat. Chuck 230 may be omitted if the wafer warpage is acceptable or absent. Lateral displacement of wafer 110 and/or chuck 230 can be restricted by limiters 244.

Separately, and possibly outside of chamber 210, a bonding layer 250 is placed on carrier 254. Bonding layer 250 can be an adhesive layer or a double-sided adhesive tape for example. A robot (not shown) aligns the carrier 254 above the wafer 110, with the bonding layer 250 facing the wafer. The carrier is released to rest on sloped surfaces of wedge spacers 260 placed on the periphery of wafer 110 to prevent the wafer from sticking to the carrier before vacuum is established in the chamber.

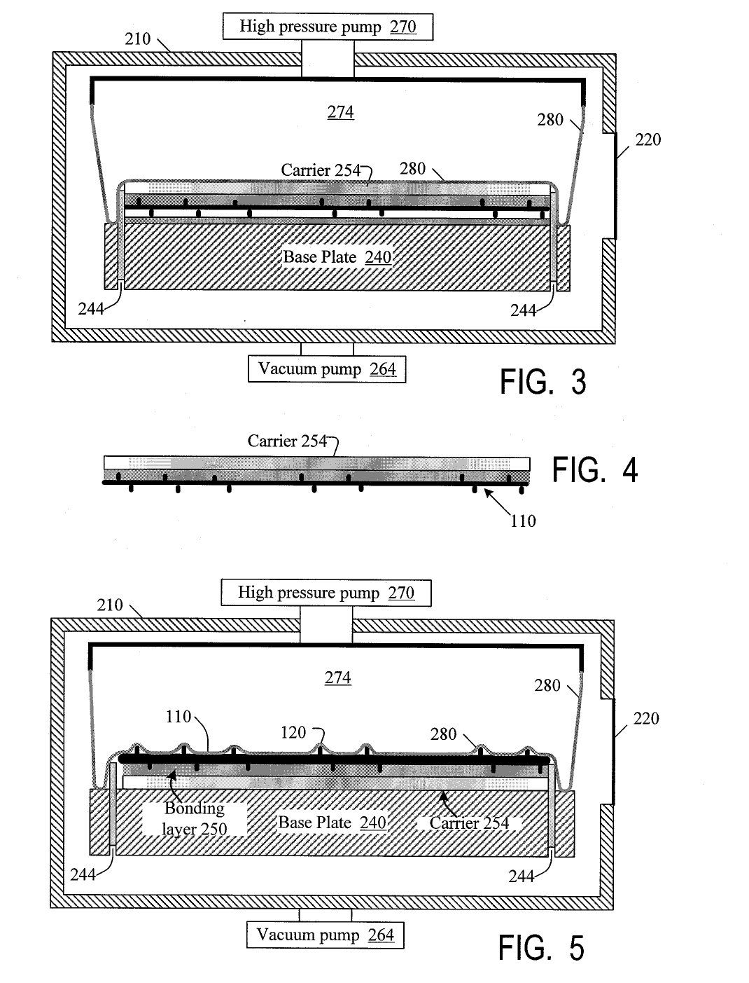

Port 220 is then closed. A vacuum pump 264 (FIG. 3) pumps down the chamber 210 to a desired vacuum level. Then the spacers 260 are moved away and the carrier 254 descends to allow the bonding layer 250 to contact the wafer 110. The limiters 244 retract so that their top surface is below the top surface of the carrier. Then a high pressure pump 270 forces gas (e.g. air) into a cavity 274 in a body 276 whose lower wall 280 is an expandable membrane. In some embodiments, membrane 280 is elastic, e.g. a silicone film of about 3 mm to 4 mm thickness. Other materials can also be used. In particular, rubber and other elastomeric materials (stretchable materials capable to quickly regain their original shape) can be used. In some embodiments, a non-elastic membrane is used with a corrugated edge. The pressure difference inside and outside of cavity 274 in chamber 210 causes the membrane 280 to expand. Membrane 280 stretches out (expands) to contact and cover the entire top surface of carrier 254, exerting a desired pressure over the carrier's entire top surface. The pressure depends on the pressure difference inside and outside of cavity 274. In some embodiments, the membrane 280 expands around the carrier 250 and wafer 110 to reach base plate 240. The drawings indicate the membrane position schematically and do not represent the actual shape (the membrane could expand sideways, for example). In some embodiments, the membrane's bottom surface is about 1.25 cm above the carrier at the stage of FIG. 2. In some embodiments, the top of body 276 does not move.

When a desired bond has been formed between the wafer and the carrier, the pressure in chamber 210 is restored to atmospheric, and the pressure difference inside and outside of cavity 274 is reduced (possibly to zero) to cause the membrane 280 to retract. In some embodiments, the bottom surface of membrane 280 is textured to prevent the membrane from sticking to carrier 254. The carrier and the wafer can now be removed from the chamber (FIG. 4) for further processing. For example, the wafer's bottom side (in the view of FIG. 4) can be subjected to etching, deposition, photolithographic patterning, ion implantation, and/or other processing.

The invention is not limited to any particular adhesive or any process that may or may not be needed to cure the adhesive. Such processes may be conducted within and/or without the chamber 210. Carrier 254 can be another semiconductor wafer (e.g. another silicon wafer), a glass wafer, or some other type.

In FIG. 5, carrier 254 is below the wafer. Electrostatic chuck 230 is omitted. The carrier is loaded into chamber 210 and placed on base plate 240. Bonding layer 250 can be placed on the carrier or the wafer 110 either inside or outside of chamber 210 before the bonding occurs. The process is otherwise similar to the one of FIGS. 2, 3. Membrane 280 may at least partially conform to the upper surface topography of wafer 110 to distribute the force on the wafer more evenly over the wafer's surface.

The invention is not limited to the embodiments described above. For example, bonding layer 250 can be deposited on wafer 110 rather than on carrier 254, or can be deposited both on the wafer and the carrier. After subsequent wafer processing, the wafer can be debonded from the carrier, or the wafer can be permanently bonded to the carrier. Wafer 110 can be replaced with a stack of semiconductor and/or non-semiconductor wafers, dies, or other types of structures. Carrier 254 can also be replaced with such a stack. In some embodiments, the pressure difference inside and outside of cavity 274 is created with only one of pumps 264, 270. For example, high pressure pump 270 can be omitted. In some embodiments, bonding layer 250 is omitted; the bond is formed by thermocompression or in some other manner.

Some embodiments include a method for bonding a first structure (e.g. 110 or 254) to a second structure (e.g. 110 or 254), the method comprising: (1) placing the first and second structures adjacent to each other; and (2) providing pressure differential at opposite sides of an expandable membrane (e.g. above 280 and below 280) to cause the expandable membrane to press on the first structure to bond the first structure to the second structure. The membrane can be an elastic membrane, or may include a non-elastic (e.g. steel) membrane with corrugated edges. In some embodiments, in operation (2) the membrane presses on the first structure over the first structure's entire side (e.g. top side) opposite to the second structure. In some embodiments, in operation (2) the membrane expands around the first structure and past the first structure's surface facing the membrane. For example, in FIG. 3, membrane 280 expands around carrier 254 and past the top surface of carrier 254 (the membrane reaches base plate 240 below the top surface of carrier 254). In FIG. 5, the membrane reaches below the top surface of wafer 110. In some embodiments, in operation (2) the membrane reaches a flat surface over which the second structure is positioned (e.g. the top surface of base plate 240), the second structure underlying the first structure. In some embodiments, in operation (2) the membrane comprises an elastic membrane conforming to conductive protrusions (e.g. 120 in FIG. 5) of a semiconductor wafer included in the first structure.

Some embodiments include a method of bonding a first structure to a second structure, the method comprising: (1) placing the first and second structures adjacent to each other, the first structure's first surface (e.g. bottom surface of 254 in FIG. 1) facing the second structure's first surface (e.g. top surface of 110); (2) providing a positive pressure on a first side of an elastic membrane (e.g. top side of 280 in FIGS. 3, 5) relative to a pressure on a second side of the elastic membrane (e.g. bottom side of 280) to cause the membrane to press on the first structure's second surface (e.g. top surface of carrier 254 in FIG. 3 or wafer 110 in FIG. 5) opposite to the first structure's first surface to bond the first and second structures' first surfaces to each other. In some embodiments, in operation (2) the elastic membrane covers the first structure's entire second surface to exert pressure on the first structure over the first structure's entire second surface (see e.g. FIGS. 3, 5).

Some embodiments include an apparatus comprising: a holding plate (e.g. 240) for holding a structure; a body (e.g. 276) whose wall comprises an expandable membrane which is operable to be expanded to reach and press on the structure; one or more pumps (e.g. 264, 270) for establishing a positive pressure inside the body relative to a pressure outside the body to cause the membrane to press on the structure.

Other embodiments and variations are within the scope of the invention, as defined by the appended claims.

1. A method for bonding a first structure to a second structure, the method comprising:
(1) placing the first and second structures adjacent to each other; and
(2) providing pressure differential at opposite sides of an expandable membrane to cause the expandable membrane to press on the first structure to bond the first structure to the second structure.

2. The method of claim 1 wherein the expandable membrane is an elastic membrane.

3. The method of claim 1 wherein in operation (2) the expandable membrane presses on the first structure over the first structure's entire side opposite to the second structure.

4. The method of claim 3 wherein in operation (2) the expandable membrane expands around the first structure and past the first structure's surface facing the expandable membrane.

5. The method of claim 4 wherein in operation (2) the expandable membrane reaches a flat surface over which the second structure is positioned, the second structure underlying the first structure.

6. The method of claim 1 wherein at least one of the first and second structures comprises a semiconductor wafer.

7. The method of claim 6 wherein the expandable membrane comprises an elastic membrane, and in operation (2) the elastic membrane conforms to conductive protrusions of a semiconductor wafer included in the first structure.

8. The method of claim 1 wherein the second structure comprises a semiconductor wafer, and operation (1) comprises placing the second structure onto an electrostatic chuck which counteracts and reduces the semiconductor wafer's warpage.

9. The method of claim 1 wherein the first structure is bonded to the second structure with adhesive.

10. The method of claim 1 wherein the pressure differential is provided by gas pressure on the opposite sides of the membrane.

11. A method of bonding a first structure to a second structure, the method comprising:
(1) placing the first and second structures adjacent to each other, the first structure's first surface facing the second structure's first surface;
(2) providing a positive pressure on a first side of an elastic membrane relative to a pressure on a second side of the elastic membrane to cause the membrane to press on the first structure's second surface opposite to the first structure's first surface to bond the first and second structures' first surfaces to each other.

12. The method of claim 11 wherein in operation (2) the elastic membrane covers the first structure's entire second surface to exert pressure on the first structure over the first structure's entire second surface.

13. The method of claim 12 wherein in operation (2) the elastic membrane expands around the first structure's second surface and past the first structure's second surface.

14. The method of claim 12 wherein in operation (2) the elastic membrane presses on conductive protrusions of a semiconductor wafer included in the first structure.

15. The method of claim 11 wherein the second structure comprises a semiconductor wafer, and operation (1) comprises placing the second structure onto an electrostatic chuck which counteracts and reduces the semiconductor wafer's warpage.

16. An apparatus comprising:
a holding plate for holding a structure;
a body whose wall comprises an expandable membrane operable to be expanded to reach and press on the structure;
one or more pumps for establishing a positive pressure inside the body relative to a pressure outside the body to cause the membrane to press on the structure.

17. The apparatus of claim 16 wherein the expandable membrane is an elastic membrane.

18. The apparatus of claim 16 wherein the expandable membrane comprises a corrugated edge.

19. The apparatus of claim 16 wherein the one or more pumps are operable to cause the membrane to reach the holding plate around the structure.

20. The apparatus of claim 16 further comprising a vacuum chamber containing the holding plate.
